(19) United States
(12) Patent Application Publication
(10) Pub. No.: US 2015/0216084 A1
(43) Pub. Date: Jul. 30, 2015

(54) ELECTRONIC ASSEMBLY

(71) Applicant: Tatung Company, Taipei (TW)

(72) Inventor: Chih-Wen Huang, Taipei (TW)

(21) Appl. No.: 14/445,071

(22) Filed: Jul. 29, 2014

(30) Foreign Application Priority Data
Jan. 29, 2014 (TW) 103103588

(51) Int. Cl. H05K 7/20

(52) U.S. Cl. CPC H05K 7/20509; H05K 7/205

(57) ABSTRACT

An electronic assembly includes a heat generating element, a heat dissipation fin set disposed above the heat generating element, a filter circuit board, and a heat conducting layer. The filter circuit board is located between the heat generating element and the heat dissipation fin set, and includes a metal layer, an electromagnetic band gap structure layer, and an insulation layer. The metal layer has a first opening and contacts the heat dissipation fin set. The electromagnetic band gap structure layer has conductive patterns. Thermal vias pass through the insulation layer and connect to the metal layer. The heat generating element contacts the conductive patterns. The insulating layer is disposed between the metal layer and the electromagnetic band gap structure layer, and has a second opening and a peripheral region aligned to the conductive patterns. The heat conducting layer contacts the heat dissipation fin set through the first and second openings.

### CROSS-REFERENCE TO RELATED APPLICATION

This application claims the priority benefit of Taiwan application serial no. 103103588, filed on Jan. 29, 2014. The entirety of the above-mentioned patent application is hereby incorporated by reference herein and made a part of this specification.

### FIELD OF THE INVENTION

The invention is related to an electronic assembly. More particularly, the invention is related to an electronic assembly that lowers electromagnetic interference.

### DESCRIPTION OF RELATED ART

In recent years, with the upgrading in the integration of integrated circuits (IC), central processing units (CPU) with high computing speeds and radio frequency integrated circuits have been widely applied in various electronic devices. However, these types of electronic components have high power consumption. Thus, in order to maintain normal working temperatures, a heat dissipation fin set is usually added to lower the temperature of these electronic components.

In general, a heat dissipation fin set is directly disposed on top of a chip, and each fin of the heat dissipation fin set may be regarded as a monopole antenna. Since a conventional heat dissipation fin set is not directly connected with the ground connection layer of the printed circuit board on the bottom of the chip, it can be regarded as a floating metal. As a result, the chip will generate noise signals that are coupled to the heat dissipation fin set. When the frequency of the noise signals are close to the resonance frequency of the heat dissipation fin set, the heat dissipation fin set becomes a good antenna structure that generates strong electromagnetic radiation. In addition, the heat dissipation fin set can also be coupled to other external circuits, which will cause interference with the electronic device.

In order to solve the aforementioned problem, conventional art has provided a method for electrically connecting a heat dissipation fin set to the ground connecting layer of the printed circuit board. This reduces the potential difference between the heat dissipation fin set and the ground connecting layer, which reduces electromagnetic radiation. However, since the circuit layout on the periphery of a chip is dense, it is not easy to find suitable ground connecting points on a printed circuit board. Further, if the noise signals of the ground connecting point itself are too high, this will cause the noise signals to be easily coupled to the heat dissipation fin set, which will increase electromagnetic radiation.

Another conventional method is to add a metal shielding cover above the heat dissipation fin set in order to reduce electromagnetic interference. However, the main function of the heat dissipation fin set is to dissipate the heat generated by the chip. When the metal shielding cover shields the heat dissipation fin set, the heat dissipating effects of the heat dissipation fine set are greatly decreased. In order to solve the heat dissipating problem, if an opening is made in the metal shield mask, so as to expose part of the heat dissipating fin set, the shielding effect of the metal shielding cover lessens.

In addition, U.S. Pat. No. 7,848,108B1 provides a heat dissipation module with a periodically patterned baseplate structure. The baseplate structure is similar to an electromagnetic band gap structure layer, used to lower the electromagnetic coupling effect between a heat generating element and the heat dissipation module. However, the periodically patterned baseplate structure must accompany a frequency band to inhibit electromagnetic radiation interference. Since the heat dissipation fin is a part of the baseplate structure, when the design is changed, the entire body must be fabricated again, which is costly and time consuming.

### SUMMARY OF THE INVENTION

The invention provides an electronic assembly, for effectively lowering the electromagnetic coupling effect between a heat generating element and a heat dissipation fin set.

The invention provides an electronic assembly. The electronic assembly includes a heat generating element, a heat dissipation fin set, a filter circuit board, and a heat conducting layer. The heat dissipation fin set is disposed above the heat generating element. The filter circuit board is located between the heat generating element and the heat dissipation fin set. The filter circuit board includes a metal layer, an electromagnetic band gap structure layer, and an insulation layer. The metal layer includes a first opening, and directly contacts the heat dissipation fin set. The electromagnetic band gap includes a plurality of conductive patterns. The heat generating element directly contacts the conductive patterns, and is connected to the metal layer through a plurality of thermal vias passing through the insulation layer. The insulation layer is disposed between the metal layer and the electromagnetic band gap structure layer. The insulation layer includes a second opening and a peripheral region. The second opening is aligned to the first opening, and is surrounded by the peripheral region. The conductive patterns are aligned to the peripheral region. The heat conducting layer is disposed on the heat generating element, and directly contacts the heat dissipation fin set through the first opening and the second opening.

In an embodiment of the invention, the conductive patterns surround the heat conducting layer.

In an embodiment of the invention, the heat dissipation fin set includes a base surface, and the metal layer includes an upper surface. The base surface contacts the upper surface.

In an embodiment of the invention, the filter circuit board further includes a plurality of thermal vias. The thermal vias pass through the insulation layer, the metal layer, and the conductive patterns. Two ends of each thermal via are respectively connected to the metal layer and the corresponding conductive pattern.

In an embodiment of the invention, the heat generating element includes a chip.

In an embodiment of the invention, the insulation layer has a top surface and a bottom surface opposite to each other. The second opening passes through between the top surface and the bottom surface. The metal layer completely covers the top surface, and the conductive patterns are contacted with the bottom surface.

In an embodiment of the invention, the conductive patterns are embedded in the bottom surface of the insulation layer. A surface of each conductive pattern is coplanar with the bottom surface of the insulation layer.

In an embodiment of the invention, the conductive patterns are located on the bottom surface of the insulation layer.

In an embodiment of the invention, the electromagnetic band gap structure layer is doped with ferromagnetic powder or ferroelectric substances.

In an embodiment of the invention, a material of the conductive materials includes metal.

In an embodiment of the invention, a material of the insulation layer includes ceramic.

Based on the above, in the invention, a filter circuit board with an electromagnetic band gap structure layer is disposed between the heat generating element and the heat dissipation fin set. This way, the electromagnetic coupling effect between the heat generating element and the heat fin dissipation fin set is lowered. In the filter circuit board, a metal layer includes a first opening, an insulation layer includes a second opening aligned to the first opening, and the conductive patterns of the electromagnetic band gap structure layer are aligned to a peripheral region of the insulation layer, exposing the second opening. Thus, the heat conducting layer disposed on the heat generating element can directly contact the heat dissipation fin set through the first opening and the second opening. This will increase the heat dissipation efficiency of the electronic assembly. Accordingly, the configuration of the filter circuit board effectively lowers the electromagnetic coupling effect between the heat generating element and the heat dissipation fin set. This inhibits noise signals from coupling to the heat dissipation fin set, and will reduce the electromagnetic radiation generated by the heat dissipation fin set. At the same time, the heat dissipation effects of the heat dissipation fin set towards the heat generating element are not affected. Therefore, the electronic assembly of the invention can have good heat dissipation effects, and can effectively inhibit noise signals, further lowering electromagnetic interference.

To make the above features and advantages of the invention more comprehensible, several embodiments accompanied with drawings are described in detail as follows.

### BRIEF DESCRIPTION OF THE DRAWINGS

FIG. 1A is a three dimensional schematic view of an electronic assembly according to an embodiment of the invention.

FIG. 1B is a cross-sectional view of the electronic assembly of FIG. 1A.

FIG. 1C is a schematic top view of the electronic assembly of FIG. 1A.

FIG. 1D is a schematic bottom view of the electronic assembly of FIG. 1A.

FIG. 2 is a cross-sectional schematic view of an electronic assembly according to another embodiment of the invention.

### DESCRIPTION OF EMBODIMENTS

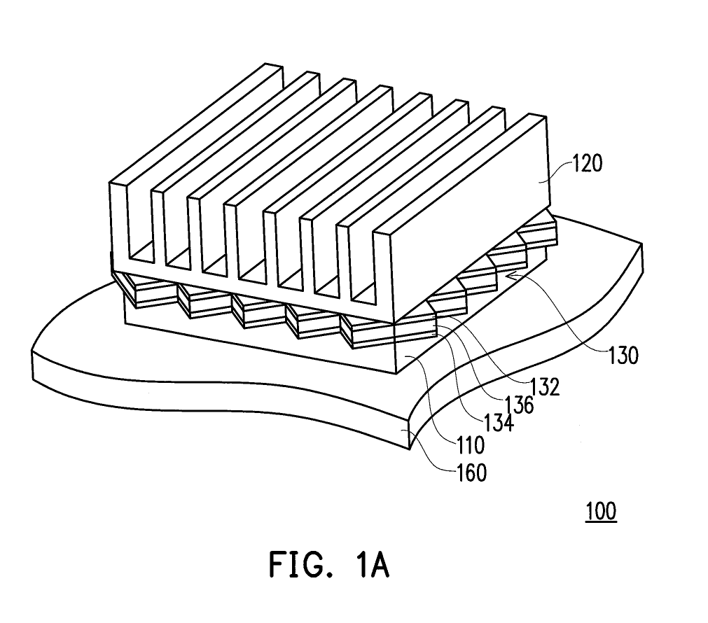

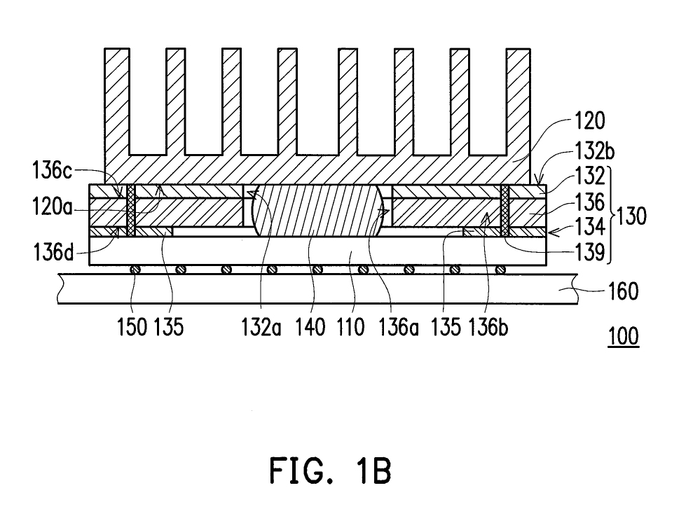

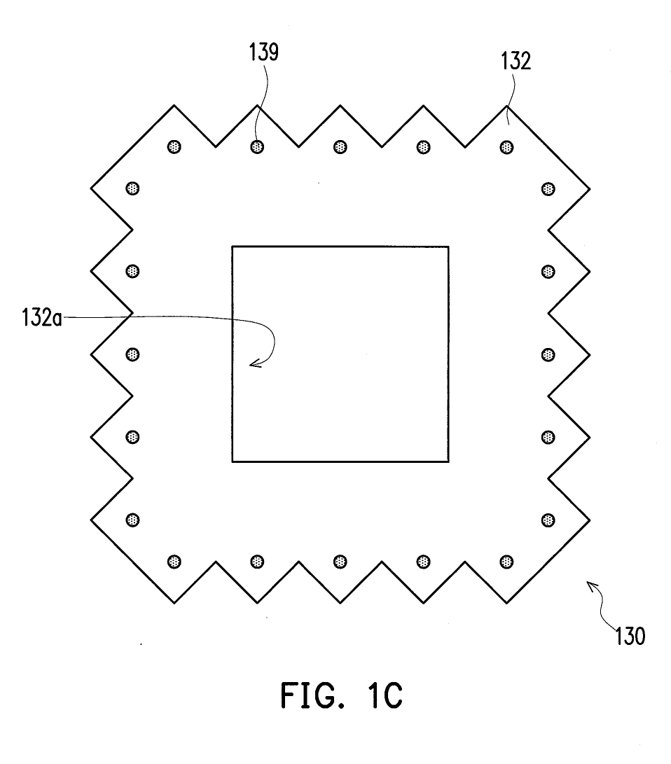

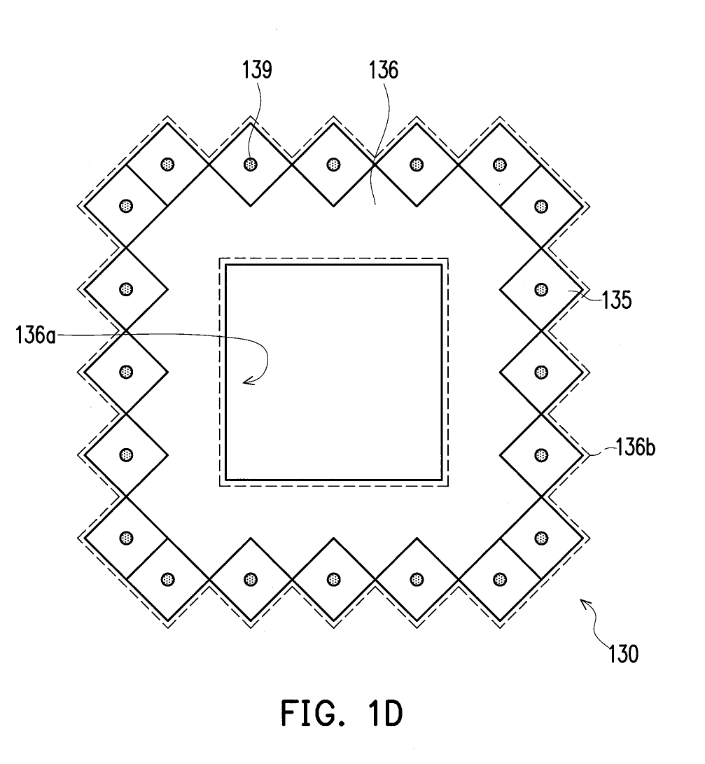

FIG. 1A is a three dimensional schematic view of an electronic assembly according to an embodiment of the invention. Referring to FIG. 1A, in the embodiment, the electronic assembly 100 includes a heat generating element 110, a heat dissipation fin set 120, and a filter circuit board 130. The heat dissipation fin set 120 is disposed above the heat generating element 110. The filter circuit board 130 is located between the heat generating element 110 and the heat dissipation fin set 120, so as to lower the electromagnetic coupling effect between the heat generating element 110 and the heat dissipation fin set 120. The specifics are described below.

FIG. 1B is a cross-sectional view of the electronic assembly of FIG. 1A. FIG. 1C is a schematic top view of the electronic assembly of FIG. 1A. FIG. 1D is a schematic bottom view of the electronic assembly of FIG. 1A. Referring to FIG. 1B to FIG. 1D, specifically, the filter circuit board 130 includes a metal layer 132, an electromagnetic band gap structure layer 134, and an insulation layer 136. The insulation layer 136 is disposed between the metal layer 132 and the electromagnetic band gap structure layer 134. The electromagnetic band gap 134 includes a plurality of conductive patterns 135, and the heat generating element 110 directly contacts the conductive patterns 135. The material of the conductive patterns 135 is, for example, metal. The material of the insulation layer 136 is, for example, ceramic or high thermal conductive insulation material. It should be noted that in order to effectively inhibit the transmission of electromagnetic waves, the electromagnetic band gap structure layer 134 of the embodiment is doped with ferromagnetic powder or ferroelectric substances.

In addition, a size of the conductive patterns 135 of the embodiment has an inverse proportion to inhibiting electromagnetic wave noises in a specific frequency range That is to say, when the conductive patterns 135 are small, many conductive patterns 135 may be disposed on an insulation layer 136 with a single size. At this time, the electromagnetic band gap structure layer 134 can inhibit electromagnetic wave noises in a higher frequency range. On the contrary, when the conductive patterns 135 are larger, only a few conductive patterns 135 may be disposed on an insulation layer 136 with a single size. At this time, the electromagnetic band gap structure layer 134 can inhibit electromagnetic wave noises in a higher frequency range a lower frequency range. Herein, the size of the conductive patterns 135 is not limited. One skilled in the art can design a suitable size for the conductive patterns 135 according to actual requirements and achieve the necessary results by referring to the previous embodiments. When the heat generating element 110 generates electromagnetic radiation, since the filter circuit board 130 is located between the heat generating element 110 and the heat fin dissipation set 120, the filter circuit board 130 can effectively inhibit the electromagnetic coupling noise signals generated by the heat generating element 110. This way, the noise signals are unable to be transmitted in the filter circuit board 130. Thus, the electromagnetic radiation generated by the heat generating element 110 is unable to enter the heat dissipation fin set 120. Thereby, the heat dissipation fin set 120 is effectively inhibited from generating electromagnetic radiations. The heat generating element 110 of the embodiment is for example, a chip, but is not limited thereto. For example, the chip can be a integrated circuit chip, including a single chip such as a graphics chip, a memory chip, a semiconductor chip or a chip module.

In further detail, the metal layer 132 includes a first opening 132a, and directly contacts the heat dissipation fin set 120. The insulation layer 136 includes a second opening 136a, a peripheral region 136b, a top surface 136c, and a bottom surface 136d opposite to the top surface 136c. The metal layer 132 completely covers the top surface 136c of the insulation layer 136. The second opening 136a passes through between the top surface 136c and the bottom surface 136d and is aligned to the first opening 132a. In addition, the second opening 136a is surrounded by the peripheral region 136b. The conductive patterns 135 are located on the bottom surface 136d of the insulation layer 136.

The electronic assembly 100 of the embodiment further includes a heat conducting layer 140. The heat conducting layer 140 is, for example, a thermal adhesive, disposed on the heat generating element 110. With the aforementioned configuration of the filter circuit board 130, the metal layer 132 includes a first opening 132a, an insulation layer 136 includes a second opening 136a aligned to the first opening 132a, and the conductive patterns 135 of the electromagnetic band gap structure layer 134 are aligned to a peripheral region 136b of the insulation layer 136 which expose the second opening 136a. Thus, the heat conducting layer 140 disposed on the heat generating element 110 can directly contact a base surface 120a of the heat dissipation fin set 120 through the first opening 132a and the second opening 136a. This will increase the heat dissipation efficiency of the electronic assembly 100. Accordingly, the configuration of the filter circuit board 130 effectively lowers the electromagnetic coupling effect between the heat generating element 110 and the heat dissipation fin set 120. This inhibits noise signals from coupling to the heat dissipation fin set 120, and will reduce the electromagnetic radiation generated by the heat dissipation fin set 120. At the same time, the heat dissipation effects of the heat dissipation fin set 120 towards the heat generating element 110 are not affected. Therefore, the electronic assembly 100 of the invention can have good heat dissipation effects, and can effectively inhibit noise signals, further lowering electromagnetic interference.

In the embodiment, the metal layer 132 includes an upper surface 132b. The base surface 120a of the heat dissipation fin set 120 contacts the upper surface 132b of the metal layer 132. That is to say, the heat dissipation fin set 120 and the metal layer 132 are not integrally formed structures. Thus, when the design of the heat dissipation fin set 120 is changed, the metal layer 132 does not need to be fabricated again with the heat dissipation fin set 120, saving fabrication time and cost. In addition, referring to FIG. 1D, in the embodiment, the shape of each of the conductive patterns 135 is, for example, rectangular. However, the invention is not limited thereto. Other embodiments can use different suitable shapes such as a hexagon or a circle.

Referring to FIG. 1B to FIG. 1D, the filter circuit board 130 of the embodiment further includes a plurality of thermal vias 139. The thermal vias 139 pass through the insulation layer 136, the metal layer 132, and the conductive patterns 135. Two ends of each of the thermal vias 139 are respectively connected to the metal layer 132 and the corresponding conductive pattern 135. This way, the connection area between the metal layer 132 and the conductive patterns 135 is increased. In detail, the ends of each of the thermal vias 139 connecting to the metal layer 132 is directly contacted with the base surface 120a of the heat dissipation fin set 120. That is to say, the heat generated by the heat generating element 110 can be transmitted to the heat dissipation fin set 120 by the heat conducting layer 140 and the thermal vias 139 at the same time. Thus, the heat dissipation effect of the filter circuit board 130 is effectively increased, which further improves the overall heat dissipation effect of the electronic assembly 100. In addition, in order to increase the application of the electronic assembly 100, the electronic assembly 100 further includes a plurality of heat conducting protrusions 150 disposed on the heat generating element 110. The heat generating element 110 is electrically connected with an external circuit 160 through the heat conducting protrusions 150.

It should be noted that the following embodiments uses similar elements and reference numbers of the previous embodiment. Similar reference numbers are used to represent similar elements, and the same descriptions are omitted. The omitted portions can be referred to in the previous embodiment, and will not be repeated herein.

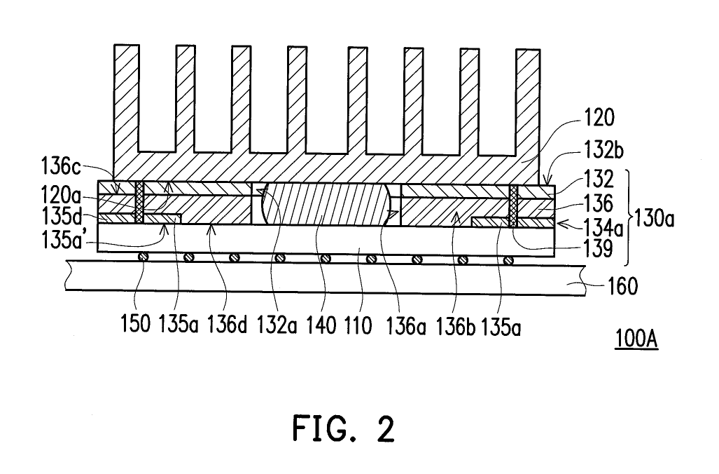

FIG. 2 is a cross-sectional schematic view of an electronic assembly according to another embodiment of the invention. Referring to FIG. 2, the electronic assembly 100A of the embodiment is similar to the electronic assembly 100 of FIG. 1A. The main differences are that the conductive patterns 135a of the electromagnetic band gap structure layer 134a are embedded in the bottom surface 136d of the insulation layer 136. In addition, a surface 135a′ of each of the conductive patterns 135a is substantially coplanar with the bottom surface 136d of the insulation layer 136. As such, the overall volume of the electronic assembly 100A is reduced, so as to satisfy the trend of being thin and light.

In addition, the invention does not limit the shape of the filter circuit board 130, 130a. Herein, the provided circuit boards 130a, 130a are double sided circuit boards, and can inhibit the noise signals of a specific frequency range. However, in other undrawn embodiments, the circuit board can also be a multi-layer circuit board. The heat conducting layer disposed on the heat generating element can contact the heat dissipation fin set through the opening of the insulation layer and the opening of the metal layer of the multi-layer circuit board. In addition, the multi-layer circuit board can inhibit noise signals from different specific frequency ranges because the conductive patterns of each layer can have different sizes. The aforementioned circuit board still belongs to a technical means adoptable in the invention, and does not depart from the scope of the invention.

To sum up, in the invention, a filter circuit board with an electromagnetic band gap structure layer is disposed between the heat generating element and the heat dissipation fin set. This way, the electromagnetic coupling effect between the heat generating element and the heat fin dissipation fin set is lowered. In the filter circuit board, a metal layer includes a first opening, an insulation layer includes a second opening aligned to the first opening, and the conductive patterns of the electromagnetic band gap structure layer are aligned to a peripheral region of the insulation layer, exposing the second opening. Thus, the heat conducting layer disposed on the heat generating element can directly contact the heat dissipation fin set through the first opening and the second opening. This will increase the heat dissipation efficiency of the electronic assembly. Accordingly, the configuration of the filter circuit board effectively lowers the electromagnetic coupling effect between the heat generating element and the heat dissipation fin set, This inhibits noise signals from coupling to the heat dissipation fin set, and will reduce the electromagnetic radiation generated by the heat dissipation fin set. At the same time, the heat dissipation effects of the heat dissipation fin set towards the heat generating element are not affected. Therefore, the electronic assembly of the invention can have good heat dissipation effects, and can effectively inhibit noise signals, further lowering electromagnetic interference.

Although the invention has been described with reference to the above embodiments, it will be apparent to one of ordinary skill in the art that modifications to the described embodiments may be made without departing from the spirit of the invention. Accordingly, the scope of the invention will be defined by the attached claims and not by the above detailed descriptions.

What is claimed is:

1. An electronic assembly, comprising:
a heat generating element;
a heat dissipation fin set, disposed above the heat generating element;
a filter circuit board, located between the heat generating element and the heat dissipation fin set, comprising:
a metal layer, comprising a first opening, and directly contacting the heat dissipation fin set;
an electromagnetic band gap structure layer, comprising a plurality of conductive patterns, wherein the heat generating element directly contacts the conductive patterns; and
an insulation layer, disposed between the metal layer and the electromagnetic band gap structure layer, wherein the insulation layer comprises a second opening and a peripheral region, wherein the second opening is aligned to the first opening and is surrounded by the peripheral region, and the conductive patterns are aligned to the peripheral region; and
a heat conducting layer, disposed on the heat generating element, wherein the heat conducting layer directly contacts the heat dissipation fin set through the first opening and the second opening.

2. The electronic assembly as claimed in claim 1, wherein the conductive patterns surround the heat conducting layer.

3. The electronic assembly as claimed in claim 1, wherein the heat dissipation fin set comprises a base surface, the metal layer comprises an upper surface, and the base surface contacts the upper surface.

4. The electronic assembly as claimed in claim 1, wherein the filter circuit board further comprises a plurality of thermal vias, wherein the thermal vias pass through the insulation layer, the metal layer, and the conductive patterns, wherein two ends of each of the thermal vias are respectively connected to the metal layer and the corresponding conductive pattern.

5. The electronic assembly as claimed in claim 1, wherein the heat generating element comprises a chip.

6. The electronic assembly as claimed in claim 1, wherein the insulation layer comprises a top surface and a bottom surface opposite to each other, the second opening passes through between the top surface and the bottom surface, the metal layer completely covers the top surface, and the conductive patterns expose a part of the bottom surface corresponding to the second opening.

7. The electronic assembly as claimed in claim 6, wherein the conductive patterns are embedded in the bottom surface, and a surface of each of the conductive patterns is coplanar with the bottom surface of the insulation layer.

8. The electronic assembly as claimed in claim 6, wherein the conductive patterns are located on the bottom surface of the insulation layer.

9. The electronic assembly as claimed in claim 1, wherein the electromagnetic band gap structure layer is doped with ferromagnetic dust or ferroelectric matter.

10. The electronic assembly as claimed in claim 1, wherein a material of the conductive patterns comprises metal.

11. The electronic assembly as claimed in claim 1, wherein a material of the insulation layer comprises ceramic.
